(19) United States
(12) Patent Application Publication
(10) Pub. No.: US 2025/0246535 A1
(43) Pub. Date: Jul. 31, 2025

(54) SEMICONDUCTOR STRUCTURE

(71) Applicant: TAIWAN SEMICONDUCTOR MANUFACTURING COMPANY LTD., HSINCHU (TW)

(72) Inventors: TZUNG-YO HUNG, CHIAYI COUNTY (TW); MAO-WEI CHIU, TAOYUAN CITY (TW); TING YU CHEN, HSINCHU CITY (TW)

(21) Appl. No.: 18/423,215

(22) Filed: Jan. 25, 2024

(51) Int. Cl. H01L 23/522

(52) U.S. Cl. CPC H01L 23/5226; H01L 23/5223; H01L 23/5227

(57) ABSTRACT

A semiconductor structure is provided. The semiconductor structure includes a front-side interconnect structure formed over a front side of a base layer and a back-side interconnect structure formed over a back side of a base layer. The front-side interconnect structure includes at least one passive element and the back-side interconnect structure includes at least one passive element. The passive element is selected from a capacitor, an inductor and a combination thereof.

### BACKGROUND

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. Integrated capacitors, a charge storage component used in many integrated circuit applications, come in various types, including metal-oxide-metal (MOM) capacitors, metal-insulator-metal (MIM) capacitors, and the like.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a fragmentary cross-sectional view of a semiconductor structure, in accordance with some embodiments of the present disclosure.

FIG. 2 is a perspective view of a unit of a metal-oxide-metal (MOM) capacitor of a semiconductor structure, in accordance with some embodiments of the present disclosure.

FIG. 3 is a fragmentary cross-sectional view of a semiconductor structure including a front-side MOM capacitor and a back-side MOM capacitor, in accordance with some embodiments of the present disclosure.

FIG. 4 is a fragmentary cross-sectional view of a semiconductor structure including a front-side MOM capacitor and a back-side MOM capacitor, in accordance with some another embodiments of the present disclosure.

FIG. 5 is a perspective view of a unit of a metal-insulator-metal (MIM) capacitor of a semiconductor structure, in accordance with some embodiments of the present disclosure.

FIG. 6 is a fragmentary cross-sectional view of a semiconductor structure including a front-side MIM capacitor and a back-side MIM capacitor, in accordance with some embodiments of the present disclosure.

FIG. 7 is a fragmentary cross-sectional view of a semiconductor structure including a front-side MIM capacitor and a back-side MIM capacitor, in accordance with some another embodiments of the present disclosure.

FIG. 8 is an exploded view showing a MOM capacitor formed above the base layer 10 and a MOM capacitor formed below the base layer, in accordance with some another embodiments of the present disclosure.

FIG. 9 is an exploded view showing a MIM capacitor formed above the base layer and a MOM capacitor formed below the base layer, in accordance with some another embodiments of the present disclosure.

FIG. 10 is an exploded view showing a MIM capacitor formed above the base layer and a MIM capacitor formed below the base layer, in accordance with some another embodiments of the present disclosure.

FIG. 11 is an exploded view showing a MOM capacitor formed above the base layer and a MIM capacitor formed below the base layer, in accordance with some another embodiments of the present disclosure.

FIG. 12 is an exploded view showing a MOM capacitor and a MIM capacitor formed above the base layer and two MOM capacitors formed below the base layer, in accordance with some another embodiments of the present disclosure.

FIG. 13A is a perspective view of an inductor of a semiconductor structure, in accordance with some embodiments of the present disclosure.

FIG. 13B is a perspective view of an inductor of a semiconductor structure, in accordance with some another embodiments of the present disclosure.

FIG. 14 is a fragmentary cross-sectional view of a semiconductor structure including a capacitor and an inductor in the front-side interconnect structure and a capacitor and an inductor in the back-side interconnect structure, in accordance with some another embodiments of the present disclosure.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Passive elements used in many integrated circuit applications, come in various types, including metal-oxide-metal (MOM) capacitors, metal-insulator-metal (MIM) capacitors, inductors, and the like. The semiconductor industry has experienced rapid growth due to improvements in the integration density of a variety of electronic components (e.g., transistors, diodes, resistors, capacitors, inductors etc.). Take capacitors as an example. As the size of a semiconductor structure shrinks, capacitance of the semiconductor structure would be sacrificed. There is a need to seek a solution to keep capacitance or even increase capacitance of the semiconductor structure.

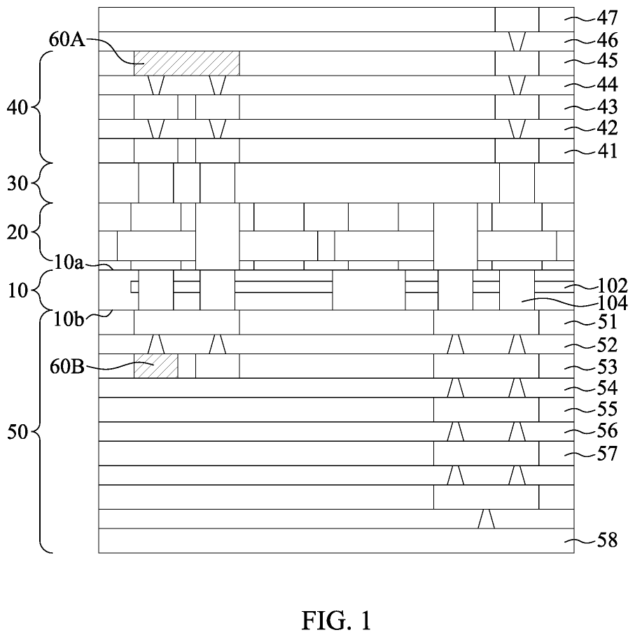

FIG. 1 is a fragmentary cross-sectional view of a semiconductor structure, which has a base layer 10, a contact-to-transistor-component layer 20, a via-between-contact-and-metallization layer (VD/VG layer) 30, a front-side interconnect structure 40 and a back-side interconnect structure 50.

The base layer 10 has a front side 10a and a back side 10b. The base layer 10 may include a substrate (wafer) 102. In some embodiments, the substrate 102 includes silicon. Alternatively or additionally, the substrate 102 includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the substrate 102 includes one or more group III-V materials, one or more group II-IV materials, or combinations thereof. In some implementations, the substrate 102 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods. The substrate 102 can include various doped regions (not shown) configured according to design requirements of a device, such as p-type doped regions, n-type doped regions, or combinations thereof. P-type doped regions (for example, p-type wells) include p-type dopants, such as boron, indium, another p-type dopant, or combinations thereof. N-type doped regions (for example, n-type wells) include n-type dopants, such as phosphorus, arsenic, another n-type dopant, or combinations thereof. In some implementations, the substrate 102 includes doped regions formed with a combination of p-type dopants and n-type dopants. The various doped regions can be formed directly on and/or in the substrate 102, for example, providing a p-well structure, an n-well structure, a dual-well structure, a raised structure, or combinations thereof. An ion implantation process, a diffusion process, and/or another suitable doping process can be performed to form the various doped regions.

The base layer 10 may further include a buried contact-to-transistor-component layer (BVD/BVG) 104 to connect the front-side interconnect structure 40 and the back-side interconnect structure 50. The buried contact-to-transistor-component layer (BVD/BVG layer) 104 includes one or more contact structures of a first type, each of which is configured to electrically couple correspondingly to a drain terminal, a source terminal, a body-bias terminal of a corresponding transistor structure in the base layer 10, or a corresponding through-silicon via (TSV) structure, the first type being referred to herein as an BVD contact structure; and one or more contact structures of a second type, each of which is configured to electrically couple to a gate terminal of a corresponding transistor structure in the base layer 10, the second type being referred to herein as an BVG contact structure. In some embodiments, the BVD contact structure is not used to electrically couple to a corresponding TSV structure in the base layer 10, but instead the BVD/BVG layer further includes one or more contact structures of a third type (not shown) which is configured to electrically couple to a corresponding TSV structure in the base layer 10.

In some embodiments, the contact-to-transistor-component layer 20 can be formed over the front side 10a of the base layer 10 and includes one or more contact structures of a first type, each of which is configured to electrically couple correspondingly to a drain terminal, a source terminal, a body-bias terminal of a corresponding transistor structure in the base layer 10, or a corresponding TSV structure in the base layer 10, the first type being referred to herein as an MD contact structure; and one or more contact structures of a second type, each of which is configured to electrically couple to a gate terminal of a corresponding transistor structure in the base layer 10, the second type being referred to herein as an MG contact structure. In some embodiments, the MD contact structure is not used to electrically couple to a corresponding TSV structure in the base layer 10, but instead the MD/MG layer further includes one or more contact structures of a third type (not shown) which is configured to electrically couple to a corresponding TSV structure in the base layer 10.

The via-between-contact-and-metallization layer (VD/VG layer) 30 can be formed over the contact-to-transistor-component layer 20 and includes one or more via-between-contact-and-metallization structures (VD/VG layer) 30 of a first type, each of which is configured to electrically couple to a corresponding MD contact structure, the first type being referred herein as an VD structure; and one or more via-between-contact-and-metallization structures (VD/VG layer) 30 of a second type, each of which is configured to electrically couple to a corresponding MG contact structure, the second type being referred to herein as a VG contact structure. In some embodiments, in which the VD/VG layer 30 includes one or more contact structures of the third type that is configured to electrically couple to a corresponding TSV structure in the base layer 10, the via-between-contact-and-metallization layer (VD/VG layer) 30 further includes one or more via-between-contact-and-metallization structures of a third type. The third type of via-between-contact-and-metallization structure is configured to electrically couple to a corresponding TSV structure in the base layer 10.

The front-side interconnect structure 40 includes a first metallization layer (M0 layer) 41, a first interconnection layer (VIA0 layer) 42; a second metallization layer (M1 layer) 43, a second interconnection layer (VIA1 layer) 44, a third metallization layer (M2 layer) 45, a third interconnection layer (VIA2 layer) 46, a fourth metallization layer (M3 layer) 47 and so on stacking along a direction away from the base layer 10, as well as at least one passive element 60A, which are provided inside a plurality of inter-layer dielectric layers formed on the via-between-contact-and-metallization layer (VD/VG layer) 30. Each of metallization layers 41, 43, 45 and 47 includes a layer of dielectric material with one or more conductive segments. Each interconnection layer 42, 44 and 46 includes a layer of dielectric material with one or more via structures. The at least one passive element 60A is formed in one or more of the metallization layers 41, 43, 45 and 47; as shown in FIG. 1, the passive element 60A is formed in the M2 layer 45 and electrically connects to the M1 layer 43. The passive element 60A may be a capacitor, an inductor or the like.

The inter-layer dielectric layers may include silicon dioxide such as undoped silica glass (USG), silicon nitride, silicon oxynitride, polyimide, spin-on glass (SOG), fluoride-doped silicate glass (FSG), carbon doped silicon oxide such as SiCOH, BLACK DIAMOND® (Applied Materials of Santa Clara, Calif.), XEROGEL®, AEROGEL®, amorphous fluorinated carbon, Parylene, BCB (bis-benzocyclobutenes), SILK® (Dow Chemical, Midland, Mich.), and/or other suitable materials. The inter-layer dielectric layers may be formed by any technique including spin-on, chemical vapor deposition (CVD), sputtering, or other suitable processes. For example, plasma enhanced (PE) CVD may be utilized to form silicon oxide from silane (SiH₄) or tetraethoxysilane (TEOS). In another example, high-density plasma (HDP) CVD may be utilized.

The back-side interconnect structure 50 can be formed over the back side 10b of the base layer 10 and includes a first buried metallization layer (BM0 layer) 51, a first buried interconnection layer (BVIA0 layer) 52, a second buried metallization layer (BM1 layer) 53, a second buried interconnection layer (BVIA1 layer) 54, a third buried metallization layer (BM2 layer) 55, a third buried interconnection layer (BVIA2 layer) 56, a fourth buried metallization layer (BM3 layer) 57, and so on stacking along a direction away from the base layer 10, a redistribution layer (RDL) 58 as well as at least one buried passive element 60B, which are provided inside a plurality of inter-layer dielectric layers formed on the back side 10b of the base layer 10. Each of buried metallization layers 51, 53, 55 and 57 includes a layer of dielectric material with one or more conductive segments. Each buried interconnection layer 52, 54 and 56 includes a layer of dielectric material with one or more via structures. The at least one buried passive element 60B is formed in one or more of the buried metallization layers 51, 53, 55 and 57. The buried passive element 60B may be capacitors, inductors or the like.

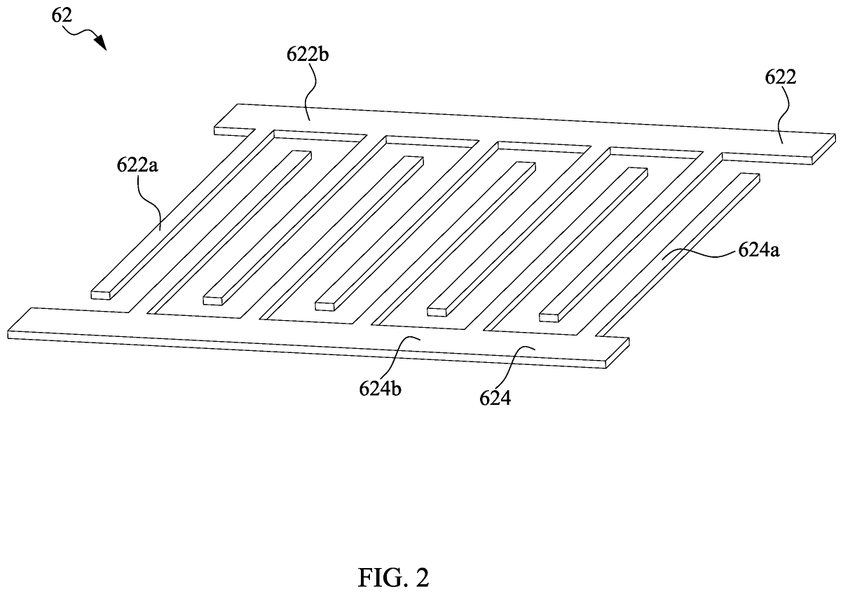

The capacitors used as the passive element 60A and the buried passive element 60B may be metal-oxide-metal (MOM) capacitors, metal-insulator-metal (MIM) capacitors or a combination thereof. FIG. 2 illustrates a perspective view of a capacitor unit of a MOM capacitor 62, which includes two metal electrodes 622 and 624 separated by dielectric materials. The metal electrode 624 includes fingers 624a, and bus 624b for interconnecting the fingers 624a. The fingers 622a and 624a are placed in an alternating pattern with a space between the neighboring fingers and the capacitance comes from the metal coupling between the neighboring fingers. Therefore, each finger 622a/624a forms a sub capacitor(s) with its neighboring fingers 622a/624a or a bus 622b/624b. The total capacitance is equivalent to the sum of the sub capacitors. In some embodiments, a space between the neighboring fingers 622a, 624a may be equal to or greater than the minimum feature size allowed by the formation technology. It should be known that a width of each finger 622a, 624a and distance are related to the technologies used and will be reduced when the integrated circuits are scaled down.

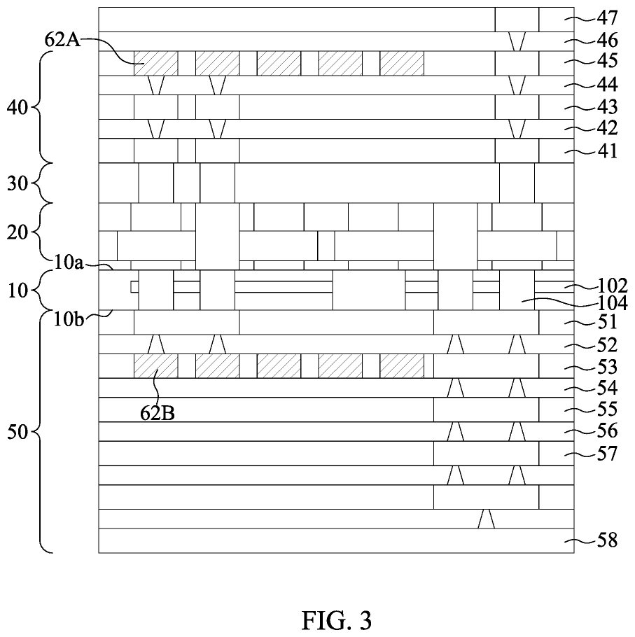

FIG. 3 is a cross-sectional view showing an exemplary embodiment of a front-side MOM capacitor 62A including one capacitor unit formed in the front-side interconnect structure 40 and a back-side MOM capacitor 62B including one capacitor unit formed in the back-side interconnect structure 50. The front-side MOM capacitor 62A may be formed in any one of the metallization layers; as shown in FIG. 3, the front-side MOM capacitor 62A is formed in the M2 layer 45 and electrically connects to the MI layer 43. The back-side MOM capacitor 62b may be formed in any one of the buried metallization layers; as shown in FIG. 3, the back-side MOM capacitor 62B is formed in the BMI layer 53 and electrically connects to the BMO layer 51. The front-side MOM capacitor 62A/back-side MOM capacitor 62B may be expanded through multiple metallization layers/buried metallization layers, although it also may be formed in only one of the metallization layers/buried metallization layer. Accordingly, the front-side MOM capacitor 62A/back-side MOM capacitor 62B may be repeatedly formed in other metallization layers/buried metallization layers, and the front-side MOM capacitors 62A in different metallization layers may be interconnected and the back-side MOM capacitors 62B in different buried metallization layers may be interconnected.

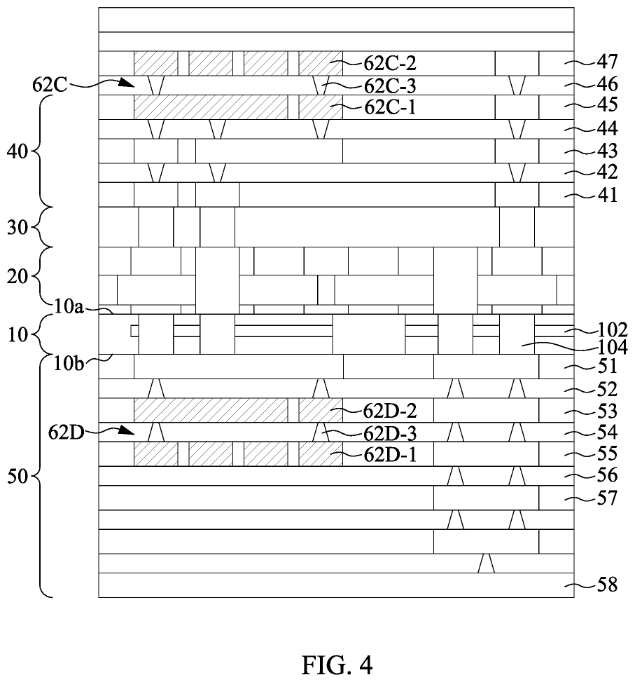

In accordance with some embodiments, FIG. 4 illustrates a cross-sectional view of a front-side MOM capacitor 62C formed by two or more capacitor units stacking along the direction away from the base layer 10, which are located in several layers of the front-side interconnect structure 40 and a back-side MOM capacitor 62D formed by two or more capacitor units stacking along a direction away from the base layer 10, which are formed in several layers of the back-side interconnect structure 50. The front-side MOM capacitor 62C includes a first metallization layer 62C-1, which is formed in the M1 layer 43 and a second metallization layer 62C-2 formed in the M2 layer 45. The first metallization layer 62C-1 connects the M0 layer 41 through vias or plugs in the VIA0 layer 42 and can be formed using a single damascene process. The first metallization layer 62C-1 and the second metallization layer 62C-2 are interconnected by vias 62C-3. In some embodiments, buses in all the layers have similar shapes and sizes and are overlapped vertically. Figures in all the layers also have similar shapes and sizes and are overlapped vertically, so the direction of the fingers in the first metallization layer 62C-1 is orthogonal to the direction of the fingers in the second metallization layer 62C-2.

The structure of the back-side MOM capacitor 62D is substantially identical or similar to that of the front-side MOM capacitor 62C. The back-side MOM capacitor 62D includes a first metallization layer 62D-1, which is formed in the BM1 layer 53 and a second metallization layer 62D-2 formed in the BM2 layer 55. The first metallization layer 62D-1 connects the BMO layer 51 through vias or plugs in the BVIA0 layer 52 and can be formed using a single damascene process. The first metallization layer 62D-1 and the second metallization layer 62D-2 are interconnected by vias 62D-3. In some embodiments, buses in all the layers have similar shapes and sizes and are overlapped vertically. Fingers in all the layers also have similar shapes and sizes and are overlapped vertically, so the direction of the fingers in the first metallization layer 62D-1 is orthogonal to the direction of the fingers in the second metallization layer 62D-2.

The MOM capacitors shown in FIGS. 3 and 4 are only examples, and there are various forms of MOM capacitors, which can be incorporated into the present invention.

A MIM capacitor can also be used in the present invention, which at least includes a first electrode and a second electrode, separated by dielectric materials. In some embodiments, the first electrode of the MIM capacitor may be formed in one of the metallization layers/buried metallization layers in the front-side interconnect structure 40/back-side interconnect structure 50, while the second electrode of the MIM capacitor may be formed between two metallization layers/buried metallization layers. The capacitance of the MIM capacitor comes from the metal coupling between the first and second electrodes.

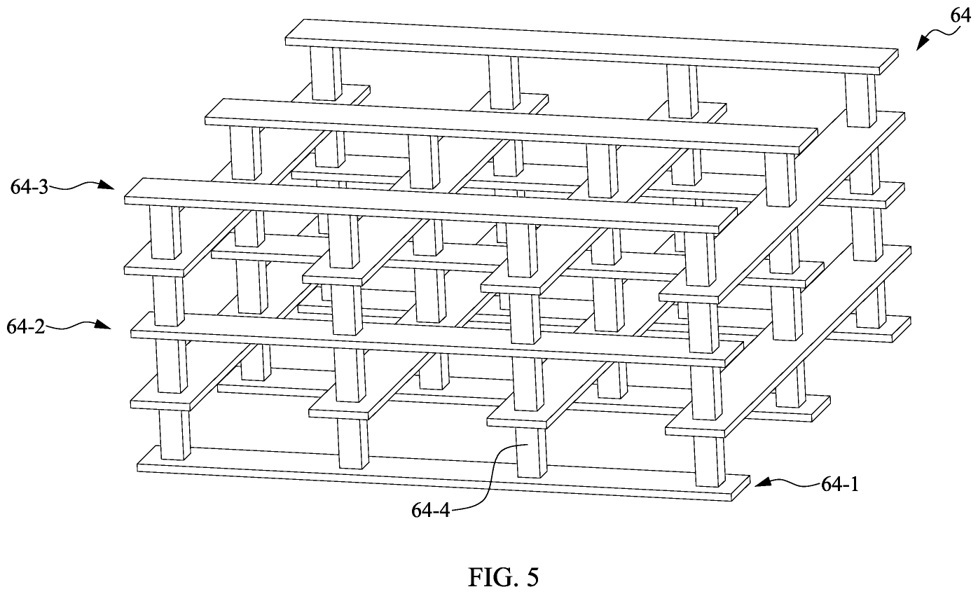

FIG. 5 illustrates a perspective view of a unit of a MIM capacitor 64 with respect to some embodiments, which includes a layer of a first electrode 64-1, a layer of a second electrode 64-2 and a layer of a third electrode 64-3, which are electrically connected through vias 64-4.

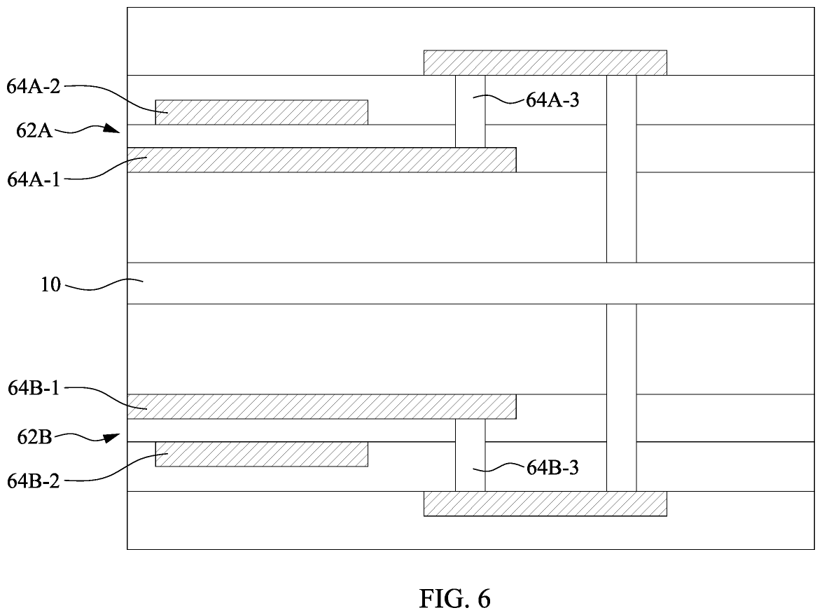

FIG. 6 illustrates an exemplary embodiment of a front-side MIM capacitor 64A formed in the front-side interconnect structure 40 and a back-side MIM capacitor 64B formed in the back-side interconnect structure 50. The front-side MIM capacitor 64A may be formed in any one of the metallization layers; as shown in FIG. 6, the front-side MOM capacitor 64A is formed in the M2 layer 45 and electrically connects to the M1 layer 43. The front-side MOM capacitor 64a includes a bottom electrode 64A-1 and a top electrode 64A-2 separated by dielectric materials. The bottom electrode 64A-1 and the top electrode 64A-2 may be formed of a conductive material such as TiN, TaN, ruthenium, aluminum, tungsten, copper, or the like, and may be formed by means of a PVD, an ECP, or a CVD method. For example, Al, a Ti/TiN/Al/Ti/TiN layer structure, a Ti/Al/Ti/TiN layer structure, a Ti/Al/TiN layer structure, a Ti/TiN/Al/Ti layer structure, a Ti/TiN/Al/TiN layer structure, Cu, or a TaN/Cu/TaN layer structure may be used to form the top and bottom electrodes. Vias may be formed through one or more of the inter-layer dielectric layers to provide electrical connectivity to the underlying circuitry. In some embodiments, the vias 64A-3 may be formed on the bottom electrode 64A-1 and/or the top electrode 64A-2 to provide electrical connectivity to the base layer 10. The structure of the back-side MIM capacitor 64B is substantially identical or similar to that of the front-side MIM capacitor 64A.

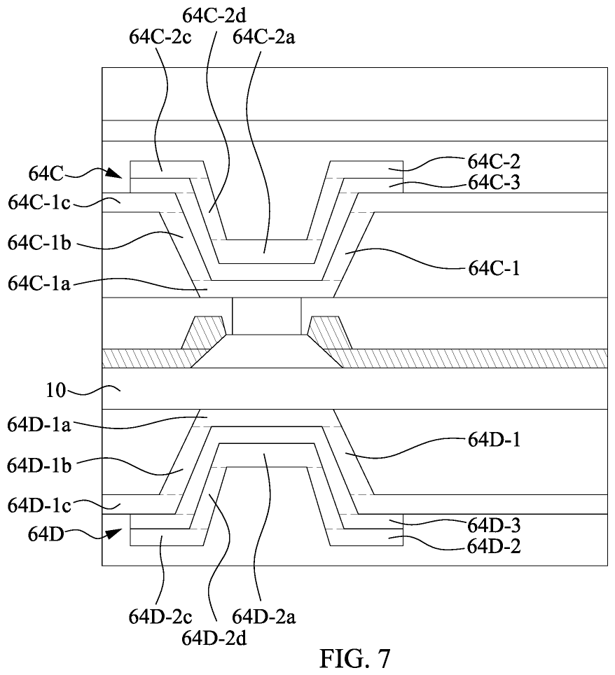

FIG. 7 illustrates a cross-sectional view showing another exemplary embodiment of a front-side MIM capacitor 64C formed in the front-side interconnect structure 40 and a back-side MIM capacitor 64D formed in the back-side interconnect structure 50. The front-side MIM capacitor 64C includes a first electrode 64C-1 and a second electrode 64C-2 separated by a dielectric layer 64C-3. The first electrode 64C-1 electrically connects to the base layer 10 through via(s). As shown in FIG. 7, the first electrode 64C-1 has a bottom portion 64C-1a connecting an underlying via, a sidewall portion 64C-1b extending from an edge of the bottom portion 64C-1a, and a top portion 64C-1c extending from a top of the sidewall portion 64C-1b. An angle between the sidewall portion 64C-1b and the bottom portion 64C-1a may be about 90° or more and less than about 180°; in some embodiments, the angle may be between about 90° to about 150°; in some embodiments, the angle may be between about 90° to about 120°. An angle between the top portion 64C-1c and the sidewall portion 64C-1b may be about 90° or more and less than about 180°; in some embodiments, the angle may be between about 90° to about 150°; in some embodiments, the angle may be between about 90° to about 120°. In some embodiments, the bottom portion 64C-1a is parallel to the top portion 64C-1c. The second electrode 64C-2 has a structure corresponding to the structure of the first electrode 64C-1. The second electrode 64C-2 has a bottom portion 64C-2a connecting an underlying dielectric layer 64C-3, a sidewall portion 64C-2b extending from an edge of the bottom portion 64C-2a, and a top portion 64C-2c extending from a top of the sidewall portion 64C-2b. An angle between the sidewall portion 64C-2b and the bottom portion 64C-2a may be about 90° or more and less than about 180°; in some embodiments, the angle may be between about 90° to about 150°; in some embodiments, the angle may be between about 90° to about 120°. An angle between the top portion 64C-2c and the sidewall portion 64C-2b may be about 90° or more and less than about 180°; in some embodiments, the angle may be between about 90° to about 150°; in some embodiments, the angle may be between about 90° to about 120°. In some embodiments, the bottom portion 64C-2a is parallel to the top portion 64C-2c.

The structure of the back-side MIM capacitor 64D is substantially identical or similar to that of the front-side MIM capacitor 64C. The back-side MIM capacitor 64D includes a first electrode 64D-1 and a second electrode 64D-2 separated by a dielectric layer 64C-3. The first electrode 64D-1 electrically connects to the base layer 10 through via(s). The first electrode 64D-1 has a top portion 64D-1a connecting an overlying via, a sidewall portion 64D-1b extending from an edge of the top portion 64D-1a, and a bottom portion 64D-1c extending from a top of the sidewall portion 64D-1b. An angle between the sidewall portion 64C-1b and the top portion 64D-1a may be about 90° or more and less than about 180°; in some embodiments, the angle may be between about 90° to about 150°; in some embodiments, the angle may be between about 90° to about 120°. An angle between the bottom portion 64D-1c and the sidewall portion 64D-1b may be about 90° or more and less than about 180°; in some embodiments, the angle may be between about 90° to about 150°; in some embodiments, the angle may be between about 90° to about 120°. In some embodiments, the top portion 64D-1a is parallel to the bottom portion 64D-1c. The second electrode 64D-2 has a structure corresponding to the structure of the first electrode 64D-1. The second electrode 64D-2 has a top portion 64D-2a connecting an overlying dielectric layer 64C-3, a sidewall portion 64D-2b extending from an edge of the top portion 64D-2a, and a bottom portion 64D-2c extending from a top of the sidewall portion 64D-2b. An angle between the sidewall portion 64C-2b and the top portion 64D-2a may be about 90° or more and less than about 180°; in some embodiments, the angle may be between about 90° to about 150°; in some embodiments, the angle may be between about 90° to about 120°. An angle between the bottom portion 64D-2c and the sidewall portion 64D-2b may be about 90° or more and less than about 180°; in some embodiments, the angle may be between about 90° to about 150°; in some embodiments, the angle may be between about 90° to about 120°. In some embodiments, the top portion 64D-2a is parallel to the bottom portion 64D-2c.

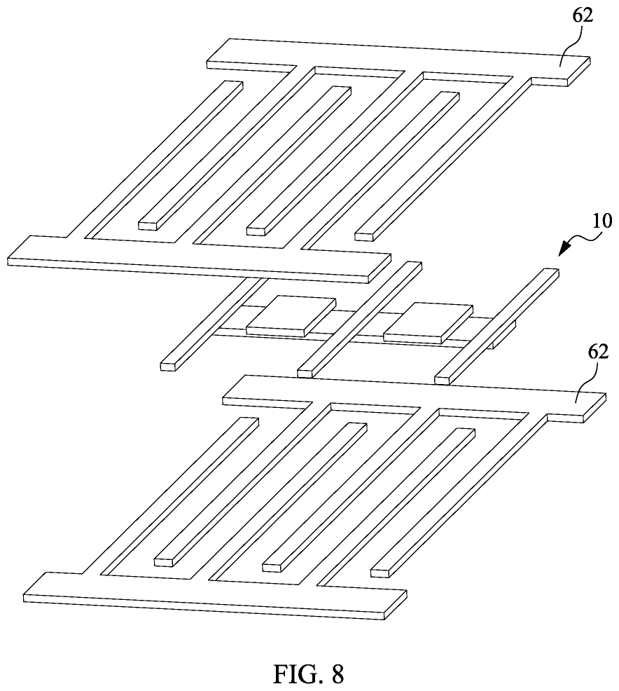

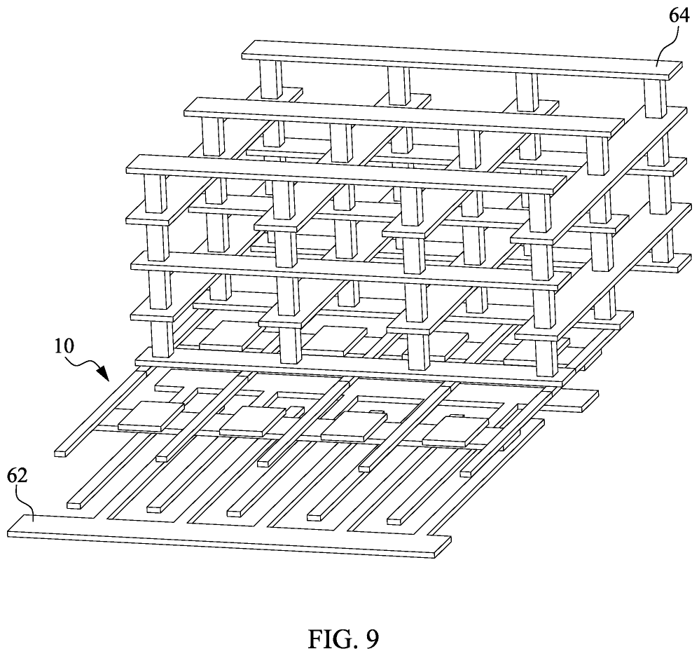

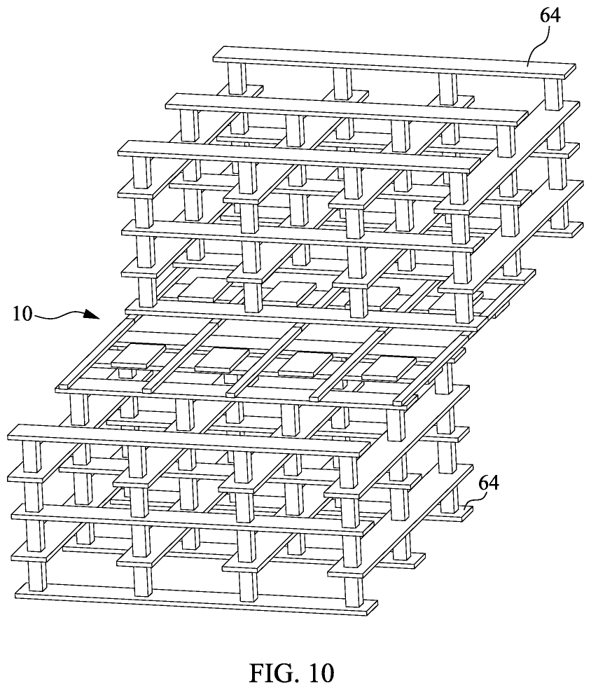

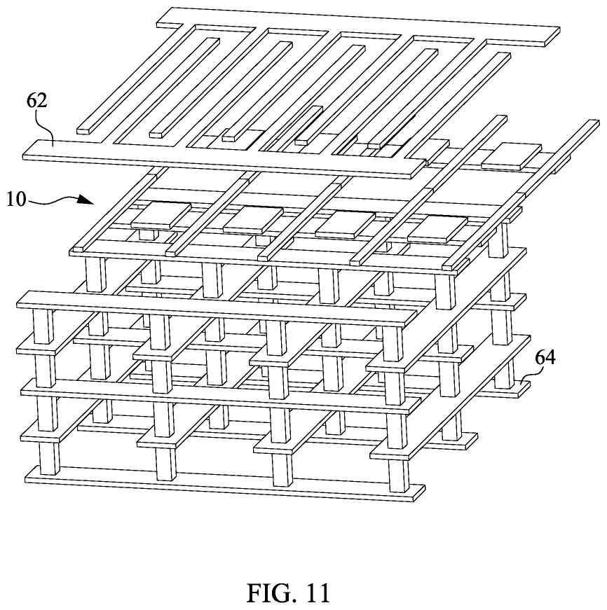

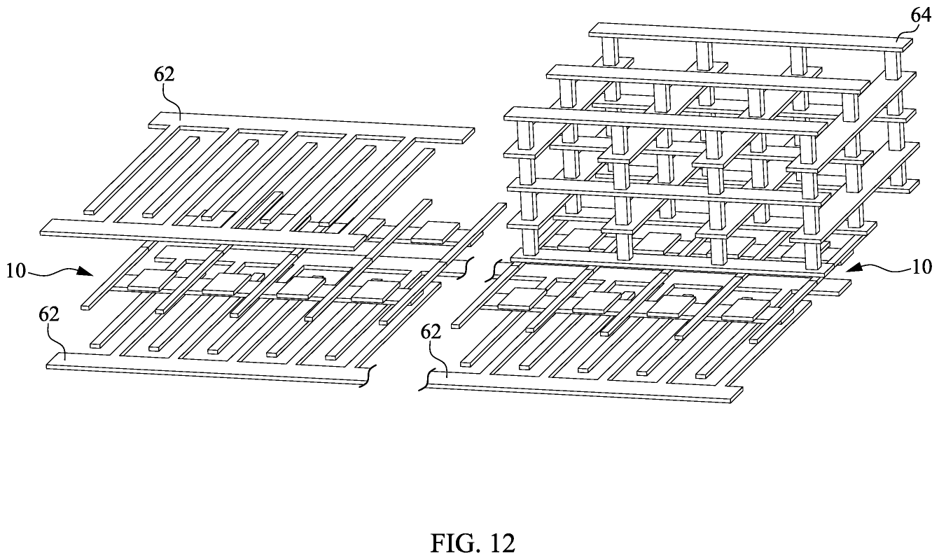

There is no any limitation to the number of capacitors or the species in either the front-side interconnect structure 40 or the back-side interconnect structure 50. For example, in some embodiments, as shown in FIG. 8, a MOM capacitor 62 is formed above the base layer 10, and a MOM capacitor 62 is formed below the base layer 10. The base layer 10 may include one or more metal-oxide-semiconductor capacitor (MOScap), one or more semiconductor devices, or the like, or a combination thereof. In some another embodiments, as shown in FIG. 9, a MIM capacitor 64 is formed above the base layer 10, and a MOM capacitor 62 is formed below the base layer 10. In some another embodiments, as shown in FIG. 10, a MIM capacitor 64 is formed above the base layer 10, and a MIM capacitor 64 is formed below the base layer 10. In some another embodiments, as shown in FIG. 11, a MOM capacitor 62 is formed above the base layer 10, and a MIM capacitor 64 is formed below the base layer 10. In some another embodiments, as shown in FIG. 12, the base layer 10 may include both of the MOScap and the semiconductor device. A MOM capacitor 62 may be formed above the MOScap of the base layer 10, and a MOM capacitor 62 may be formed below the MOScap of the base layer 10 while a MIM capacitor 64 is formed above the semiconductor device of the base layer 10 and a MOM capacitor 62 may be formed below the semiconductor device of the base layer 10. In another embodiments, a MOM capacitor 62 may be formed above the semiconductor device of the base layer 10, and a MOM capacitor 62 may be formed below the semiconductor device of the base layer 10 while a MIM capacitor 64 is formed above the MOScap of the base layer 10 and a MOM capacitor 62 may be formed below the MOScap of the base layer 10.

In some embodiments, under the same unit area, the semiconductor structure of the present invention with the MOM capacitors in both the front-side interconnect structure 40 and the back-side interconnect structure 50 may achieve approximately two times of the voltage stabilizing capacitance as compared with a semiconductor structure including a MOM capacitor only formed in the front-side interconnect structure 40. In some another embodiments, as the semiconductor structure may shrink in size, forming MOM capacitors with a reduced size in both the front-side interconnect structure 40 and the back-side interconnect structure 50 may keep capacitance as compared with a semiconductor structure with a regular size including a MOM capacitor only formed in the front-side interconnect structure 40.

In some embodiments, the passive element 60A and buried passive element 60B may be inductors, which are formed in the front-side interconnect structure 40 and in the back-side interconnect structure 50, respectively, as shown in FIG. 1. Each inductor includes a coil element having one or more turns (e.g., two turns in the present example). Various turns of the coil element are connected through via features in the metal layer in some embodiments.

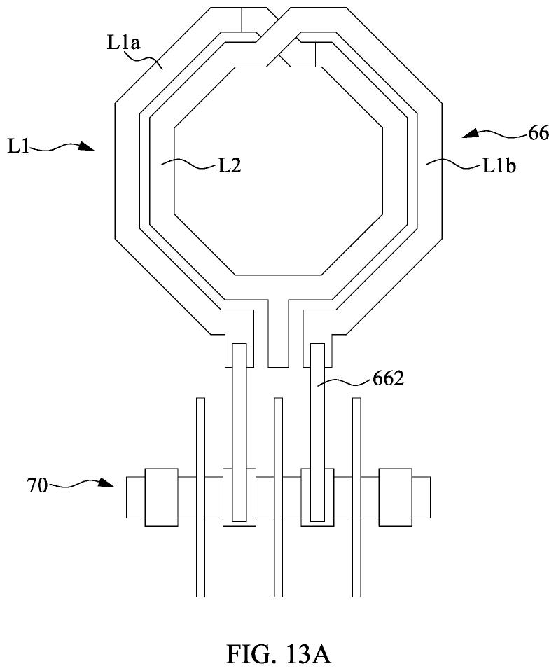

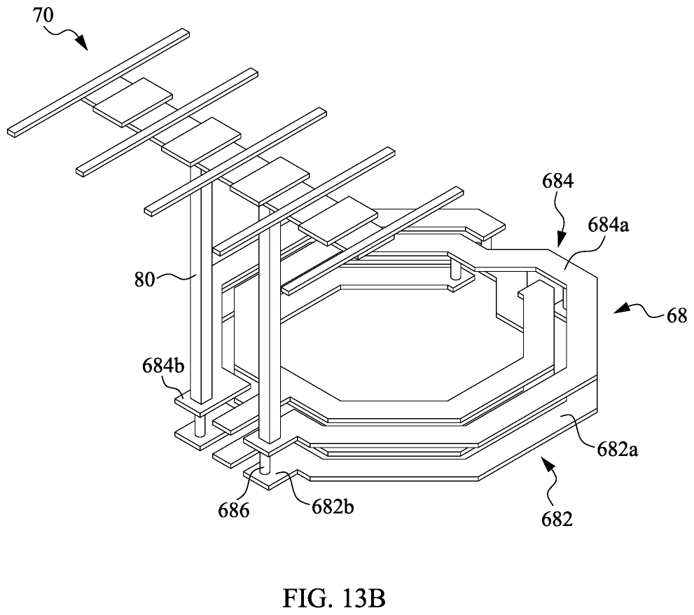

FIG. 13A illustrates an example of an inductor 66, which can be located in one of the metallization layers 41, 43, 45 and 47/one of the buried metallization layers 51, 53, 55 as shown in FIG. 1. The inductor 66 includes a primary winding L1 and a secondary winding L2. The primary winding L1 includes a first winding segment (or coil) L1a and a second winding segment (or coil) L1b. The first winding segment L1 connects one end of the second winding L2 and the second winding segment L2 connects to the other end of the second winding L2. As shown in FIG. 13A, in some embodiments, the primary winding L1 and the secondary winding L2 are octagonal. However, the topology of each of the primary winding L1 and the secondary winding L2 can be varied; for example, the primary winding L1 and the secondary winding L2 may be rectangular. The inductor 66 connects a device 70 through two ports 662. The inductor 66 and the device 70 are placed in the same plane.

FIG. 13B is a perspective view of inductor 68 constructed according to aspects of the present disclosure. In some embodiments, the inductor 68 includes a first coil 682, a second coil 684 and two contacts 686. The first coil element 682 includes a first spiral structure 682a and two first ports 682b and the second coil element 684 includes a second spiral structure 684a corresponding to the first spiral structure 682a and two second ports 684b. The first coil 682 and a second coil 684 may be substantially parallel to each other. The contacts 686 connect the first ports 682b of the first coil 682 and the second ports 684b of the second coil 684. The contacts 686 are formed between the first ports 682b and the second ports 684b. The inductor 68 connects to a device 70 through metal bars 80. In some embodiments, as shown in FIG. 13B, one end of the metal bar 80 connects the device 70 and the other end of the metal bar 80 connects to a top of the second ports 684b. The device 70 may be substantially parallel to the first coil 682 and may be substantially parallel to the second coil 684. In another some embodiments, one end of the metal bar 80 connects the device 70 and the other end of the metal bar 80 connects to a bottom of the first ports 684b. The inductor 68 and the device 70 may be placed in different metallization layers so such inductor 68 would be suitable for a semiconductor structure with a reduced size.

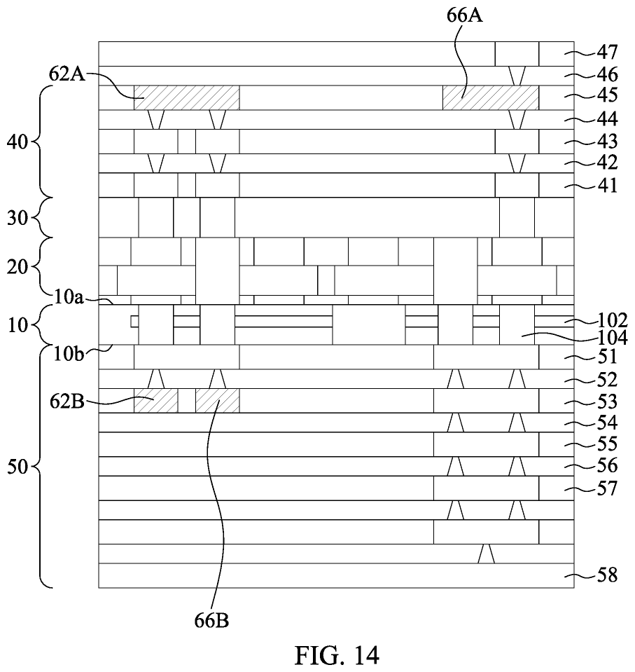

As shown in FIG. 14, in some embodiments, there are two or more passive element 60A formed in the front-side interconnect structure 40 including a capacitor (e.g., a front-side MOM capacitor 62A) and an inductor (e.g., a front-side inductor 66A) in the same interconnection layer (e.g., the M2 layer 45); and there are two or more buried passive elements 60B formed in the back-side interconnect structure 50 including a capacitor (e.g., a back-side MOM capacitor 62B) and an inductor (e.g., a back-side inductor 66B) in the same interconnection layer (e.g., the BM1 layer 53). In some another embodiments, there are two or more passive element 60A formed in the front-side interconnect structure 40 including a capacitor and an inductor in different interconnection layers; and there are two or more buried passive elements 60B formed in the back-side interconnect structure 50 including a capacitor and an inductor in different interconnection layers. The number, species and arrangement of the passive elements in the front-side interconnect structure and those in the back-side interconnect structure can be varied according to desired function and layout of the semiconductor structure.

The semiconductor structure of the present invention includes at least one passive element in the front-side interconnect structure above the base layer and at least one passive element in the back-side interconnect structure below the base layer, which achieves better performance and/or saves area compared to a semiconductor structure with a passive element only in the front-side interconnect structure. Under the same unit area, a semiconductor structure of the present invention with capacitors in both the front-side interconnect structure and the back-side interconnect structure may achieve approximately two times of the voltage stabilizing capacitance as compared with a semiconductor structure including a capacitor only formed in the front-side interconnect structure. When forming capacitors/inductors in both of the front-side interconnect structure and the back-side interconnect structure, the size of the semiconductor structure can be reduced. Alternatively, if the size of the semiconductor structure retain unchanged, more function devices may be located in the front-side interconnect structure, which makes the layout of the semiconductor structure more flexible.

In some embodiments, a semiconductor structure comprises a base layer having a front side and a back side; a contact-to-transistor-component layer formed over the front side of the substrate; a via-between-contact-and-metallization layer formed over the contact-to-transistor-component layer; a front-side interconnect structure formed over the via-between-contact-and-metallization layer and comprising: a first metallization layer and a plurality of second metallization layers, separated by a plurality of interconnection layers; at least one front-side capacitor formed in the second metallization layers; and at least one front-side inductor formed in the second metallization layers; and a back-side interconnect structure formed on the back side of the base layer and comprising: a first buried metallization layer and a plurality of second buried metallization layers, separated by a plurality of buried interconnection layer; at least one back-side capacitor formed in the second buried metallization layers; and at least one back-side inductor formed in the second buried metallization layers.

In some embodiments, a semiconductor structure comprises a base layer having a front side and a back side; a front-side interconnect structure formed over the front side of the base layer and comprising: a first metallization layer and a plurality of second metallization layers, separated by a plurality of interconnection layers; and at least one passive element formed in the second metallization layers; and a back-side interconnect structure formed on the back side of the base layer and comprising: a first buried metallization layer and a plurality of second buried metallization layers, separated by a plurality of buried interconnection layer; and at least one buried passive element formed in the second buried metallization layers.

In some embodiments, a semiconductor structure comprises a base layer; a front-side interconnect structure formed over the base layer and comprising: a first metallization layer and a plurality of second metallization layers, separated by a plurality of interconnection layers; and at least one front-side capacitor formed in the second metallization layers; and a back-side interconnect structure formed under the base layer and comprising: a first buried metallization layer and a plurality of second buried metallization layers, separated by a plurality of buried interconnection layer; at least one back-side capacitor formed in the second buried metallization layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor structure comprising:
a base layer having a front side and a back side;
a contact-to-transistor-component layer formed over the front side of the substrate;
a via-between-contact-and-metallization layer formed over the contact-to-transistor-component layer;
a front-side interconnect structure formed over the via-between-contact-and-metallization layer and comprising:
a first metallization layer and a plurality of second metallization layers, separated by a plurality of interconnection layers;
at least one front-side capacitor formed in the second metallization layers; and
at least one front-side inductor formed in the second metallization layers; and
a back-side interconnect structure formed on the back side of the base layer and comprising:
a first buried metallization layer and a plurality of second buried metallization layers, separated by a plurality of buried interconnection layer;
at least one back-side capacitor formed in the second buried metallization layers; and
at least one back-side inductor formed in the second buried metallization layers.

2. The semiconductor structure of claim 1, wherein the at least one front-side capacitor and the at least one front-side inductor are formed in a same one of the second metallization layers.

3. The semiconductor structure of claim 1, wherein the at least one back-side capacitor and the at least one back-side inductor are formed in a same one of the second buried metallization layers.

4. The semiconductor structure of claim 1, wherein the at least one front-side capacitor is selected from a metal-oxide-metal (MOM) capacitor, a metal-insulator-metal (MIM) capacitor or a combination thereof; and the at least one back-side capacitor is selected from a MOM capacitor, a MIM capacitor or a combination thereof, wherein the at least one front-side capacitor and the at least one back-side capacitor are identical.

5. The semiconductor structure of claim 1, wherein the at least one front-side capacitor is selected from a MOM capacitor, a MIM capacitor or a combination thereof; and the at least one back-side capacitor is selected from a MOM capacitor, a MIM capacitor or a combination thereof, wherein the at least one front-side capacitor and the at least one back-side capacitor are different.

6. The semiconductor structure of claim 1, wherein the at least one front-side capacitor comprises a MOM capacitor and a MIM capacitor formed in the second metallization layers; and the at least one back-side capacitor comprises two MOM capacitors formed in the second buried metallization layers.

7. The semiconductor structure of claim 1, wherein the inductor comprises:
a primary winding comprising a first winding segment and a second winding segment; and
a secondary winding, wherein the first winding segment connects one end of the second winding and the second winding segment connects to the other end of the second winding,
wherein the primary winding and the secondary winding are in a same plane.

8. The semiconductor structure of claim 1, wherein the inductor comprises:
a first coil comprising a first spiral structure and two first ports;
a second coil comprising a second spiral structure corresponding to the first spiral structure and two second ports; and
two contacts formed between the first ports and the second ports,
wherein the first coil and a second coil are substantially parallel to each other.

9. A semiconductor structure comprising:
a base layer having a front side and a back side;
a front-side interconnect structure formed over the front side of the base layer and comprising:
a first metallization layer and a plurality of second metallization layers, separated by a plurality of interconnection layers; and
at least one passive element formed in the second metallization layers; and
a back-side interconnect structure formed on the back side of the base layer and comprising:
a first buried metallization layer and a plurality of second buried metallization layers, separated by a plurality of buried interconnection layer; and
at least one buried passive element formed in the second buried metallization layers.

10. The semiconductor structure of claim 9, wherein the at least one passive element is selected from a MOM capacitor, a MIM capacitor, an inductor or a combination thereof; and the at least one buried passive element is selected from a MOM capacitor, a MIM capacitor, an inductor or a combination thereof.

11. The semiconductor structure of claim 10, wherein each MOM capacitor comprises one capacitor unit having two metal electrodes separated by dielectric materials, wherein each metal electrode comprises fingers, and bus for interconnecting the fingers.

12. The semiconductor structure of claim 11, wherein the MOM capacitor in the front-side interconnect structure is formed in one of the second metallization layers; and the MOM capacitor in the back-side interconnect structure is formed in one of the second buried metallization layers.

13. The semiconductor structure of claim 10, wherein the MOM capacitor each comprises two or more capacitor units stacking in the second metallization layers or the second buried metallization layers along a direction away from the base layer, wherein the capacitor unit comprises two metal electrodes separated by dielectric materials, and wherein each metal electrode comprises fingers, and bus for interconnecting the fingers.

14. The semiconductor structure of claim 10, wherein the MIM capacitor each comprises a layer of a first electrode, a layer of a second electrode and a layer of a third electrode, which are electrically connected.

15. A semiconductor structure, comprising:
a base layer;
a front-side interconnect structure formed over the base layer and comprising:
a first metallization layer and a plurality of second metallization layers, separated by a plurality of interconnection layers; and
at least one front-side capacitor formed in the second metallization layers; and
a back-side interconnect structure formed under the base layer and comprising:
a first buried metallization layer and a plurality of second buried metallization layers, separated by a plurality of buried interconnection layer; and
at least one back-side capacitor formed in the second buried metallization layers.

16. The semiconductor structure of claim 15, wherein the at least one front-side capacitor is a MOM capacitor or a MIM capacitor and a back-side capacitor is a MOM capacitor or a MIM capacitor.

17. The semiconductor structure of claim 15, wherein the at least one front-side capacitor comprises two or more identical front-side capacitors and the at least one back-side capacitor comprises two or more identical back-side capacitors.

18. The semiconductor structure of claim 15, wherein the at least one front-side capacitor comprises a MOM capacitor and a MIM capacitor formed in the second metallization layers; and the at least one back-side capacitor comprises two MOM capacitors formed in the second buried metallization layers.

19. The semiconductor structure of claim 15, wherein the at least one front-side capacitor is different from the at least one back-side capacitor.

20. The semiconductor structure of claim 15, wherein the at least one front-side capacitor and the at least one back-side capacitor are identical.
